(19) United States
(12) Patent Application Publication
(10) Pub. No.: US 2009/0227099 A1
(43) Pub. Date: Sep. 10, 2009

(54) METHOD OF FORMING A SEMICONDUCTOR DEVICE HAVING A STRESSED ELECTRODE AND SILICIDE REGIONS

(76) Inventor: STEFAN ZOLLNER, Hopewell Junction, NY (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 12/043,372

(22) Filed: Mar. 6, 2008

(51) Int. Cl. H01L 21/4763; H01L 21/44

(52) U.S. Cl. 438/586; 438/622; 438/682; 257/E21.495; 257/E21.476

(57) ABSTRACT

In one embodiment, a method of forming a semiconductor device includes forming a first device region and a second device region over a substrate, wherein the first device region comprises a first region with a first dopant type, the second device region comprises a second region with a second dopant type, and the first dopant type is different than the second dopant type. The method also includes forming a stress layer over the first device region and the second device region, removing the stress layer from the second device region, and forming a first metal layer over the second device region while the stress layer is over the first device region.

### BACKGROUND

1. Field

This disclosure relates generally to semiconductor devices, and more specifically, to forming a stressed gate electrode and silicide regions.

2. Related Art

As more functionality and increased speed are required for semiconductor devices, the semiconductor industry wants to increase performance of semiconductor devices. Various methods exist for increasing performance, but processing can be complex. Thus, a need exists for methods of processing semiconductor devices that have improved performance.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-section of a portion of a semiconductor device having an NMOS device and a PMOS device and a stress layer formed over the semiconductor device in accordance with an embodiment;

FIG. 2 illustrates the semiconductor device of FIG. 1 after patterning the stress layer in accordance with an embodiment;

FIG. 3 illustrates the semiconductor device of FIG. 2 while annealing the semiconductor device in accordance with an embodiment;

FIG. 4 illustrates the semiconductor device of FIG. 3 after forming a first metal layer in accordance with an embodiment;

FIG. 5 illustrates the semiconductor device of FIG. 4 while annealing the semiconductor device in accordance with an embodiment;

FIG. 6 illustrates the semiconductor device of FIG. 5 after removing unreacted portions of the first metal layer in accordance with an embodiment;

FIG. 7 illustrates the semiconductor device of FIG. 6 after removing the patterned stress layer in accordance with an embodiment;

FIG. 8 illustrates the semiconductor device of FIG. 7 after forming a second metal layer over the semiconductor device in accordance with an embodiment;

FIG. 9 illustrates the semiconductor device of FIG. 8 while annealing the semiconductor device in accordance with an embodiment; and

FIG. 10 illustrates the semiconductor device of FIG. 9 after removing unreacted portions of the second metal layer in accordance with an embodiment.

### DETAILED DESCRIPTION

### Summary

Some embodiments include the following items. Item 1: A method of forming a semiconductor device (10), the method comprising: forming a first device region (14) and a second device region (16) over a substrate (12), wherein: the first device region (14) comprises a first region with a first dopant type, the second device region (16) comprises a second region with a second dopant type, and the first dopant type is different than the second dopant type; forming a stress layer (38) over the first device region (14) and the second device region (16); removing the stress layer (38) from the second device region (16); and forming a first metal layer (44) over the second device region (16) while the stress layer (38, 40) is over the first device region. Item 2: The method of item 1, further comprising: forming a first silicide (48, 50, 52) and a first unreacted portion of the first metal layer; and removing the first unreacted portion. Item 3: The method of items 1 or 2, further comprising: removing the stress layer (38, 40) over the first device region (14) after forming the first silicide (48, 50, 52) and the first unreacted portion; forming a second metal layer (54) over the first device region (14) after removing the stress layer; (38, 40) forming a second silicide (58, 60, 62) and a second unreacted portion of the second metal layer (54); and removing the second unreacted portion. Item 4. The method of items 1, 2, or 3, wherein forming the first silicide (48, 50, 52) and the first unreacted portion comprises reacting the first metal layer (44) with a first semiconductor material (12, 24); and forming the second silicide and the second unreacted portion comprises reacting the second metal layer (54) with a second semiconductor material (12, 22). Item 5. The method of item 4, wherein the first semiconductor material (12, 24) and the second semiconductor material (12, 22) are a material selected from the group consisting of the substrate (12), wherein the substrate comprises a semiconductor material; a gate electrode (22, 24), wherein the gate electrode comprises a semiconductive material; and different portions of a semiconductor layer. Item 6: The method of items 1, 2, 3, 4, or 5, wherein forming the first metal layer comprises forming the first metal layer over the stress layer of the first device region. Item 7: The method of items 1, 2, 3, 4, 5, or 6, wherein the first device region comprises a first gate stack (22, 20) for an N-type transistor; and the second device region comprises a second gate stack (24, 21) for a P-type transistor. Item 8: The method of items 1, 2, 3, 4, 5, 6, or 7, wherein removing the stress layer from over the second device region comprises exposing the second gate stack. Item 9: The method of items 1, 2, 3, 4, 5, 6, 7, or 8, further comprising annealing (42) the semiconductor device before forming the first metal layer (44). Item 10: The method of item 1, wherein the stress layer (38, 40) comprises a tensile stress.

Some embodiments include the following items. Item 11. A method of forming a semiconductor device (10), the method comprising: forming a first gate stack (22, 20) over a substrate (12); forming a second gate stack (24, 21) over the substrate (12); forming a stress layer (38, 40) over the first gate stack (22, 20); exposing the second gate stack (24, 21); forming a first metal layer (44) over the stress layer (38, 40) and in contact with the second gate stack (24, 21); and reacting the first metal layer (44) with the second gate stack (24, 21). Item 12. The method of item 11, wherein forming the stress layer (38, 40) over the first gate stack (22, 20) and exposing the second gate stack (24, 21) comprise: forming the stress layer (38, 40) over the first gate stack (22, 20) and the second gate stack (24, 21); and removing the stress layer (38, 40) over the second gate stack (24, 21). Item 13. The method of items 11 or 12, wherein reacting the first metal layer (44) with the second gate stack (24, 21) comprises: forming a silicide (48, 50, 52) over the second gate stack (24, 21); and forming unreacted portions of the first metal layer (44). Item 14. The method of items 11, 12, or 13, further comprising: forming a second metal layer (54) over the first gate stack (22, 20); and reacting the second metal layer (54) with the first gate stack (22, 20).

Some embodiments include the following items. Item 15. A method of forming a semiconductor device (10), the method comprising: forming a first device region (14) and a second device region (16) over a substrate (12), wherein: the first device region comprises a first gate stack (22, 20) and a first region with a first dopant type, the second device region comprises a second gate stack (24, 21) and a second region with a second dopant type, and the first dopant type is different than the second dopant type; forming a stress layer (38, 40) over the first device region (14); forming a first metal layer (44) in contact with the second gate stack (24, 21) and over the stress layer (40) in the first device region (14); forming a first silicide (28, 50, 52) and a first unreacted portion of the first metal layer (44); removing the first unreacted portion; and removing the stress layer (40) over the first device region (14) after forming the first silicide (48, 50, 52) and the first unreacted portion. Item 16. The method of item 15, wherein removing the stress layer over the first device region occurs after removing the first unreacted portion. Item 17. The method of items 15 or 16, further comprising: forming a second metal layer (54) over the first device region (14) after removing the stress layer (40); forming a second silicide (58, 60, 62) and a second unreacted portion of the second metal layer (54); and removing the second unreacted portion. Item 18. The method of items 15, 16, or 17, further comprising annealing (42) the semiconductor device before forming the first metal layer. Item 19. The method of items 15, 16, 17, or 18, wherein the stress layer (38, 40) comprises a tensile stress. Item 20. The method of items 15, 16, 17, 18 or 19, wherein the stress layer (38, 40) comprises silicon and nitrogen; and the first metal layer comprises platinum.

A method for forming a semiconductor device having an NMOS device with silicide regions and a stressed gate electrode and a PMOS device with silicide regions is described below. During processing, the stress layer used to form the NMOS stressed gate electrode can be used as a hard mask when forming the silicide regions for the PMOS device.

FIG. 1 illustrates a cross-section of a portion of a semiconductor device 10 having an NMOS region, which includes an NMOS device 14, and a PMOS region, which includes a PMOS device 16, separated electrically by an isolation region 18, such as shallow trench isolation (STI), in accordance with an embodiment. The NMOS device 14 includes current electrodes, which in the embodiment illustrated are source/drain regions 26 and 27, within a substrate 12 and separated by a control electrode 22, which in the embodiment illustrated is a gate electrode. The substrate 12 is a semiconductor substrate and can be any semiconductor material or combinations of materials, such as gallium arsenide, silicon germanium, silicon-on-insulator (SOI), silicon, monocrystalline silicon, the like, and combinations of the above. The NMOS device 14 has a gate stack that includes the gate electrode 22 and the dielectric layer 20. Adjacent the gate electrode 22 are spacers, which are illustrated as L-shaped spacer 30 and sidewall spacer 34. A skilled artisan recognizes that in this embodiment the L-shaped spacer 30 and the sidewall spacer 34 surround the gate electrode 22 on all sides and hence appear in cross-section as either two L-shaped spacers or two sidewall spacers. However, in other embodiments, other spacer configurations can be used. For example, the L-shaped spacer 30 may not be present.

The PMOS device 16 includes current electrodes, which in the embodiment illustrated are source/drain regions 28 and 29, within the substrate 12 and separated by a control electrode 24, which in the embodiment illustrated is a gate electrode. The PMOS device 16 has a gate stack that includes the gate electrode 24 and the dielectric layer 21. Adjacent the gate electrode 24 are spacers, which are illustrated as L-shaped spacer 32 and sidewall spacer 36, which are similar to L-shaped spacer 30 and sidewall spacer 34.

Formed in the z-direction between the gate electrodes 22 and 24 and the substrate 12 is the dielectric layer 20, which will serve as the gate dielectric for the gate stacks that include the gate electrodes 22 or 24 and the gate dielectric.

A skilled artisan knows the materials and processes used to form gate stacks, source/drain regions and spacers. For example, the gate electrodes 22 and 24 may be polysilicon, a metal gate, or combinations of the above. The dielectric layers 20 and 21 may be silicon dioxide, a high dielectric constant material, such as hafnium oxide, or combinations of the above. The dielectric layers 20 and 21 may or may not be the same material. Various processes can be used, such as chemical vapor deposition (CVD), atomic layer deposition (ALD), physical vapor deposition (PVD) (e.g., sputtering), growth processes, the like, and combinations of the above.

Formed over the gate stacks for the NMOS device 14 and the PMOS device 16 is a stress layer 38, as illustrated in FIG. 1. In one embodiment, the stress layer 38 is silicon nitride formed using a deposition process, such as CVD, ALD, PVD, the like, and combinations of the above. The stress layer 38, in one embodiment, is a tensile stress layer. In one embodiment, the stress layer 38 is approximately 30 to approximately 80 nanometers thick. In one embodiment, the stress layer 38 includes silicon, nitrogen, and hydrogen. In one embodiment, the stress layer is silicon nitride.

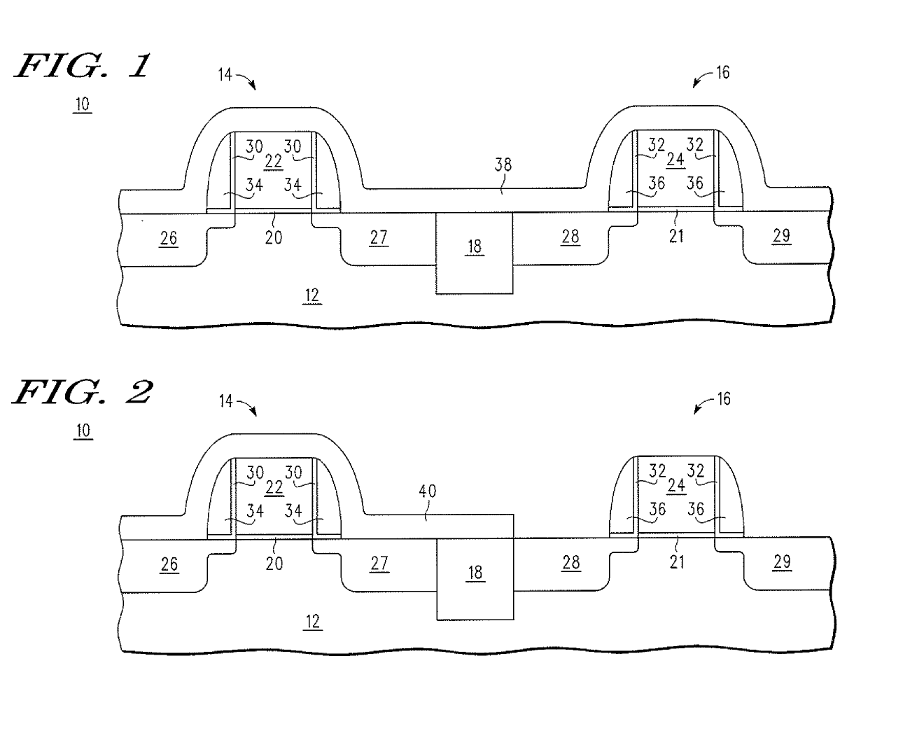

FIG. 2 illustrates the semiconductor device of FIG. 1 after patterning the stress layer 38 to form a patterned stress layer 40, in accordance with an embodiment. The stress layer 38 can be patterned by forming a patterned photoresist layer using photolithography followed by an etch process. In the embodiment where the stress layer 38 is silicon nitride, the etch process includes using chemistry including oxygen and fluorinated hydrocarbon gases. When forming the pattered stress layer 40, a portion of the stress layer 38 that was over the PMOS device 16 is removed and the gate electrode 24 and source/drain regions 28 and 29 are exposed.

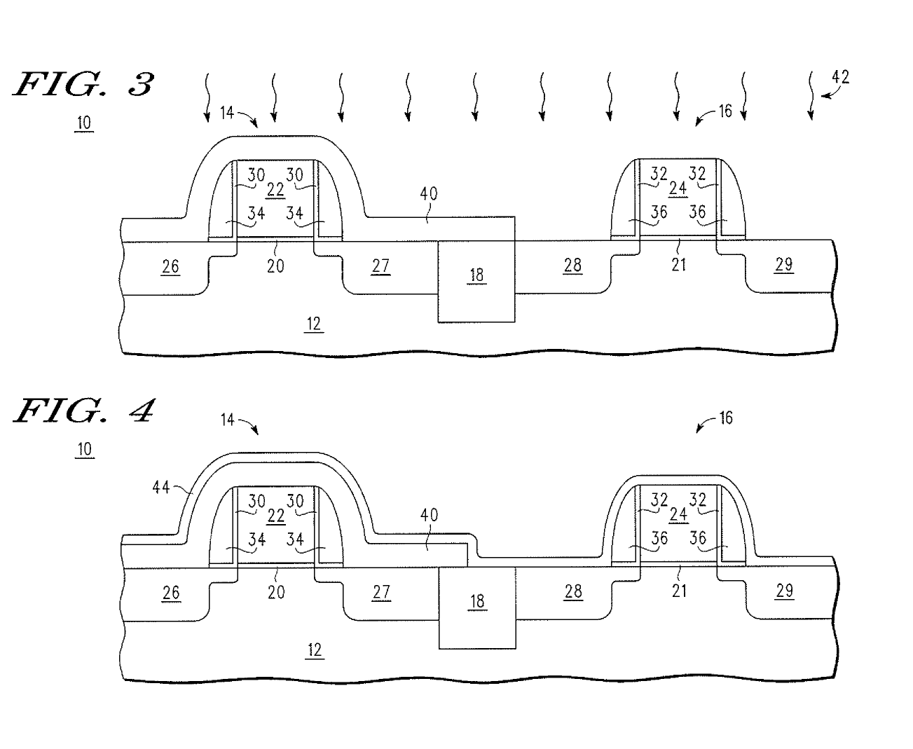

After patterning the stress layer 38, an (first) anneal 42 may be performed as illustrated in FIG. 3. The anneal may be a rapid thermal anneal (RTA). In one embodiment, the anneal occurs in an inert ambient at a temperature between approximately 1000 to approximately 1100 degrees Celsius for approximately 3 to approximately 10 seconds. The anneal 42 activates the dopants in the source/drain regions 26-29. In addition, the anneal 42 transfers the stress from the patterned stress layer 40 to the gate electrode 22 to form a stressed gate electrode 22. If the patterned stress layer 40 has a tensile stress, the performance of the NMOS device 14 will be improved due the induced stress transfer from the stress layer 40 to the NMOS device 14. The details resulting in this improved performance are not understood in the industry.

After performing the anneal 42, a first metal layer 44 is formed over the substrate 12 in accordance with an embodiment illustrated in FIG. 4. The first metal layer 44 is a metal that will be used to form a silicide for the electrodes of the PMOS device 16. Any suitable metal layer can be used. In one embodiment, the first metal layer 44 includes platinum (Pt). The first metal layer 44 can be formed by a deposition process, such as CVD, ALD, PVD, the like, and combinations of the above. In one embodiment, the first metal layer 44 is approximately 3 to approximately 30 nanometers of Pt.

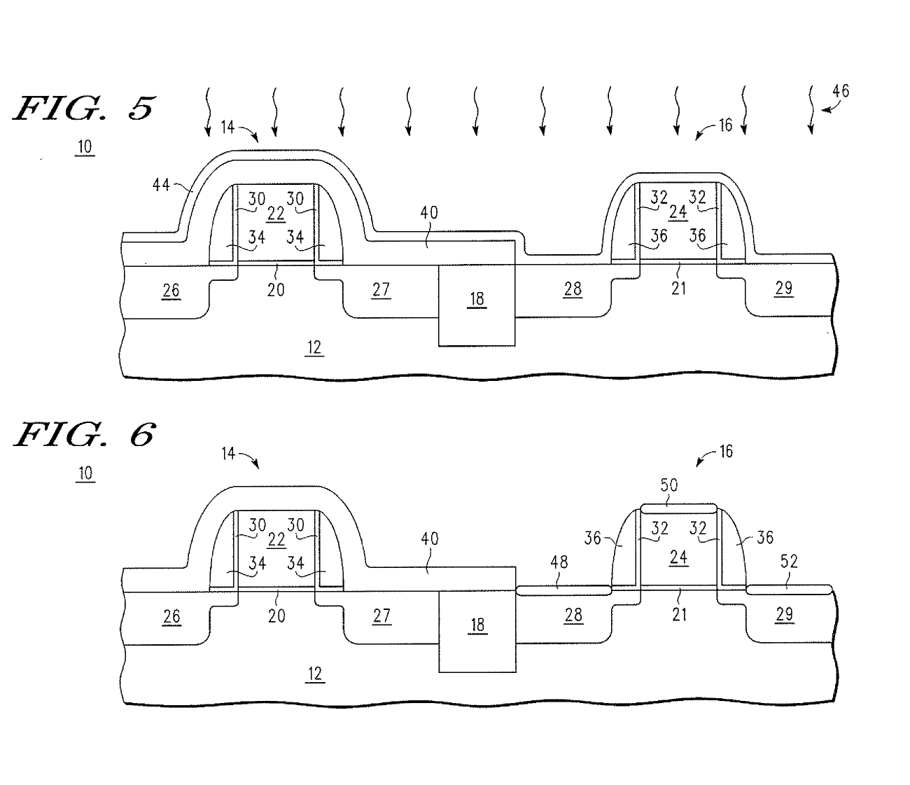

After forming the first metal layer 44, an (second) anneal 46 is performed to create silicides or silicide regions 48 and 52 within source/drain regions 28-29 and silicide or silicide region 50 over gate electrode 24, as shown in FIG. 5. The anneal 46 may be a RTA process where the semiconductor device 10 is subjected to an inert ambient and heated to a temperature of less than 600 degrees Celsius for a duration of less than 30 seconds to react a metal, such as Pt, in the first metal layer 44 with underlying areas that include crystalline silicon, such as the source/drain regions 28-29 and the gate electrode 24. In some embodiments, the source/drain regions 28-29 or the gate electrode 24 may not include crystalline silicon. Since a silicide will only be formed in a region that includes crystalline silicon, if the source/drain regions 28-29 or the gate electrode 24 does not include crystalline silicon, the silicide will not be formed in this region.

After performing the anneal 46, the first metal layer 44 includes reacted portions, which form the silicide, and unreacted portions. During a removal process, such as an etch process using aqua regia, the unreacted portions are removed and only the reacted portions remain. In the embodiment illustrated in FIG. 6 unreacted portions are removed from all areas shown in FIG. 6 except over the source/drain regions 28-29 and the gate electrode 24. Because in the embodiment illustrated, the patterned stress layer 40 does not include crystalline silicon, no silicide is formed in the NMOS region. Even if the stress layer 40 is silicon nitride, silicide will not be formed over with the stress layer 40 because silicon bound to oxygen or nitrogen in the form of amorphous silicon dioxide or amorphous silicon nitride will not form silicide when exposed to metal and annealed. Only silicon atoms in a four-fold coordination chemically bonded to other silicon or similar chemical elements will form silicide when exposed to metal and annealed. In this chemical configuration, silicon is usually crystalline in CMOS devices. In the embodiment depicted in FIG. 6, the unreacted portions of the first metal layer 44 include all portions over the NMOS device 14 (e.g. the gate electrode 22, the spacers 30 and 34, the source/drain regions 26 and 27), the isolation region 18, and the spacers 32 and 36.

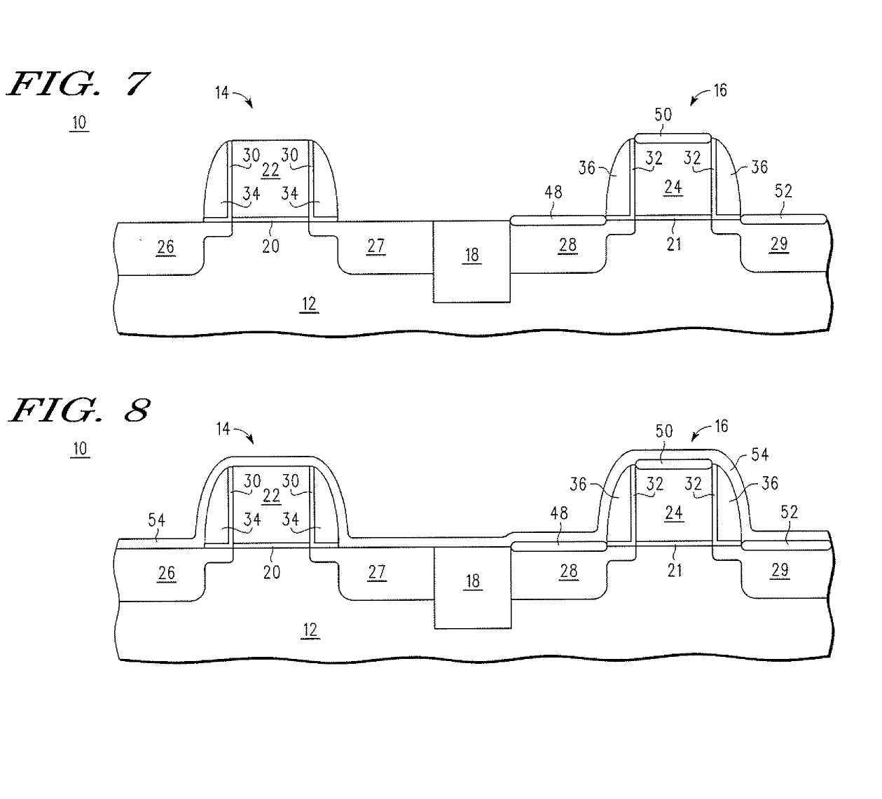

After forming the silicide regions 48, 50, and 52, the patterned stress layer 40 is removed as illustrated in FIG. 7. In one embodiment, a hot phosphoric acid clean is used to remove the patterned stress layer 40. In one embodiment, the hot phosphoric acid clean occurs at a temperature between approximately 100 to approximately 200 degrees Celsius.

After removing the patterned stress layer 40, a second metal layer 54 is formed over the semiconductor substrate 12, as illustrated in FIG. 8. The second metal layer 54 is used to form silicide regions for the NMOS device 14 and hence the material chosen for the second metal layer 54 should be a material suitable for forming an appropriate silicide with the gate electrode 22, source/drain regions 26-27, or both. In one embodiment, the second metal layer 54 includes cobalt, nickel, titanium, erbium, another rare earth metal, the like, or combinations of the above. The second metal layer 54 can be formed by any suitable process, such as CVD, ALD, PVD, the like, or combinations of the above. In one embodiment, the second metal layer 54 is approximately 3 to approximately 20 nanometers thick.

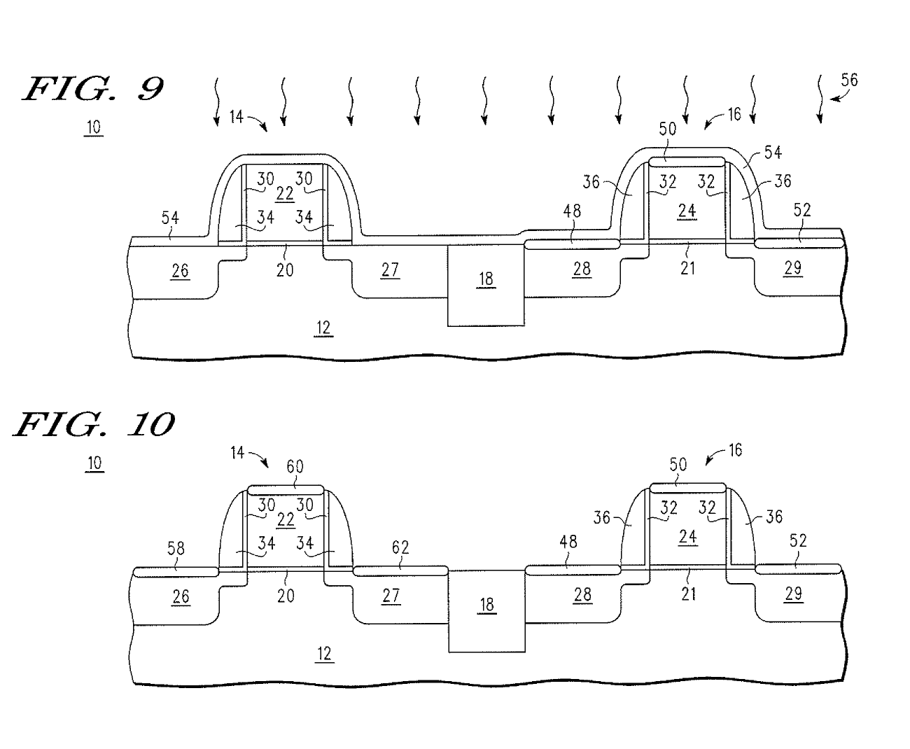

Similar to the anneal 46, a silicide is formed during an (third) anneal 56. FIG. 9 illustrates the anneal 56. In one embodiment, the anneal 56 has the same conditions as the anneal 46; in another embodiment, the anneals 46 and 56 are different. In one embodiment, the anneal 56 is an RTA anneal that occurs at a temperature of approximately 350 degrees Celsius for less than approximately 30 seconds. In another embodiment, for example if erbium is used as the second metal, the anneal 56 occurs at a temperature of approximately 650 degrees Celsius for less than approximately 90 seconds.

As a result of the anneal 56, the second metal layer 54 includes reacted portions, which form silicide or silicide regions, and unreacted portions. During a removal process, such as an etch process using aqua regia or a chemistry including hydrochloric acid (HCI), the unreacted portions are removed and only the reacted portions remain. In the embodiment illustrated in FIG. 10, unreacted portions are removed from all areas shown in FIG. 10 except over the source/drain regions 26-27 and the gate electrode 22. In the embodiment depicted in FIG. 10, the unreacted portions of the first metal layer 44 include all portions overlying the PMOS device 16, e.g. the gate electrode 22, the spacers 32 and 36, the source/drain regions 28 and 29), the isolation region 18, and the spacers 30 and 34. In other words in the embodiment of FIG. 10, silicides or silicide regions 58, 60, and 62 are formed using the second metal 54 over the source/drain regions 26, the gate electrode 22, and the source/drain regions 27, respectively.

By now it should be appreciated that there has been provided a processing method for providing improved performance while decreasing processing complexity. In regards to improved performance, NMOS mobility is enhanced by using a stress layer and external resistance is reduced by using a silicide, such as PtSi, for the PMOS device and a silicide, such as NiSi, for the NMOS device. In regards to decreasing processing complexity, the stress layer is used not only to create stress in an underlying gate electrode but serves the dual function of also serving as a hard mask during the dual silicide formation. This desirably decreases photolithography steps, which are error-prone and expensive.

Although the invention is described herein with reference to specific embodiments, various modifications and changes can be made without departing from the scope of the present invention as set forth in the claims below. For example, all the silicide regions that are formed in figures need not be formed. Furthermore, the process sequences described in the embodiments above may be performed in a different order or some steps may be removed. For example, the anneals 46 and 56 may not be performed. Although the invention has been described with respect to specific conductivity types or polarity of potentials, skilled artisans appreciated that conductivity types and polarities of potentials may be reversed. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

What is claimed is:

1. A method of forming a semiconductor device, the method comprising:
forming a first device region and a second device region over a substrate, wherein:
the first device region comprises a first region with a first dopant type,
the second device region comprises a second region with a second dopant type, and
the first dopant type is different than the second dopant type;
forming a stress layer over the first device region and the second device region;
removing the stress layer from the second device region; and
forming a first metal layer over the second device region while the stress layer is over the first device region.

2. The method of claim 1, further comprising:
forming a first silicide and a first unreacted portion of the first metal layer; and
removing the first unreacted portion.

3. The method of claim 2, further comprising:
removing the stress layer over the first device region after forming the first silicide and the first unreacted portion;
forming a second metal layer over the first device region after removing the stress layer;
forming a second silicide and a second unreacted portion of the second metal layer; and
removing the second unreacted portion.

4. The method of claim 3, wherein forming the first silicide and the first unreacted portion comprises reacting the first metal layer with a first semiconductor material; and forming the second silicide and the second unreacted portion comprises reacting the second metal layer with a second semiconductor material.

5. The method of claim 4, wherein the first semiconductor material and the second semiconductor material are a material selected from the group consisting of the substrate, wherein the substrate comprises a semiconductor material; a gate electrode, wherein the gate electrode comprises a semiconductive material; and different portions of a semiconductor layer.

6. The method of claim 1, wherein forming the first metal layer comprises forming the first metal layer over the stress layer of the first device region.

7. The method of claim 1, wherein the first device region comprises a first gate stack for an N-type transistor; and the second device region comprises a second gate stack for a P-type transistor.

8. The method of claim 1, wherein removing the stress layer from over the second device region comprises exposing the second gate stack.

9. The method of claim 1, further comprising annealing the semiconductor device before forming the first metal layer.

10. The method of claim 1, wherein the stress layer comprises a tensile stress.

11. A method of forming a semiconductor device, the method comprising:
forming a first gate stack over a substrate;
forming a second gate stack over the substrate;
forming a stress layer over the first gate stack;
exposing the second gate stack;
forming a first metal layer over the stress layer and in contact with the second gate stack; and
reacting the first metal layer with the second gate stack.

12. The method of claim 11, wherein forming the stress layer over the first gate stack and exposing the second gate stack comprise:
forming the stress layer over the first gate stack and the second gate stack; and
removing the stress layer over the second gate stack.

13. The method of claim 11, wherein reacting the first metal layer with the second gate stack comprises:
forming a silicide over the second gate stack; and
forming unreacted portions of the first metal layer.

14. The method of claim 11, further comprising:
forming a second metal layer over the first gate stack; and
reacting the second metal layer with the first gate stack.

15. A method of forming a semiconductor device, the method comprising:
forming a first device region and a second device region over a substrate, wherein:
the first device region comprises a first gate stack and a first region with a first dopant type,
the second device region comprises a second gate stack and a second region with a second dopant type, and
the first dopant type is different than the second dopant type;
forming a stress layer over the first device region;
forming a first metal layer in contact with the second gate stack and over the stress layer in the first device region;
forming a first silicide and a first unreacted portion of the first metal layer;
removing the first unreacted portion; and
removing the stress layer over the first device region after forming the first silicide and the first unreacted portion.

16. The method of claim 15, wherein removing the stress layer over the first device region occurs after removing the first unreacted portion.

17. The method of claim 16, further comprising:
forming a second metal layer over the first device region after removing the stress layer;
forming a second silicide and a second unreacted portion of the second metal layer; and
removing the second unreacted portion.

18. The method of claim 15, further comprising annealing the semiconductor device before forming the first metal layer.

19. The method of claim 15, wherein the stress layer comprises a tensile stress.

20. The method of claim 15, wherein the stress layer comprises silicon and nitrogen; and the first metal layer comprises platinum.
